(19) United States
(12) Patent Application Publication
(10) Pub. No.: US 2007/0195843 A1
(43) Pub. Date: Aug. 23, 2007

(54) Nitride semiconductor laser device and method for fabricating the same

(76) Inventors: Satoshi Tamura, Osaka (JP); Norio Ikedo, Osaka (JP)

Correspondence Address: MCDERMOTT WILL & EMERY LLP, 600 13TH STREET, N.W., WASHINGTON, DC, 20005-3096, US

(21) Appl. No.: 11/637,690

(22) Filed: Dec. 13, 2006

(30) Foreign Application Priority Data
Feb. 22, 2006 (JP) 2006-045645

(51) Int. Cl. H01S 5/00

(52) U.S. Cl. 372/45.01

(57) ABSTRACT

A nitride semiconductor laser device has a buried type structure including an active layer sandwiched between an n-type cladding layer and a p-type cladding layer; and a current blocking layer having an opening for confining a current flowing to the active layer. In the buried type structure, a regrown layer made of a nitride semiconductor layer including In (such as an InGaN layer or an AlInGaN layer) and doped with a p-type impurity is formed on the current blocking layer so as to cover the opening of the current blocking layer.

### CROSS-REFERENCE TO RELATED APPLICATIONS

This application claims priority under 35 U.S.C. §119 on Patent Application No. 2006-045645 filed in Japan on Feb. 22, 2006, the entire contents of which arc hereby incorporated by reference.

### BACKGROUND OF THE INVENTION

The present invention relates to a nitride semiconductor laser device and a method for fabricating the same, and more particularly, it relates to a nitride semiconductor laser device having a buried type current blocking structure and a method for fabricating the same.

Currently, a group III-V nitride-based compound semiconductor including group III elements of aluminum (Al), gallium (Ga) and indium (In) and a group V element of nitrogen (N), typified by gallium nitride (GaN) and represented by a general formula, InₓGa_{y}Al_{1-x-y}N (wherein 0<X≦1, 0≦Y≦1 and X +Y <1), i.e., what is called a nitride semiconductor (hereinafter referred to as a GaN-based semiconductor), is regarded remarkable. With respect to, for example, an optical device, a light emitting diode (LED) using a nitride semiconductor is used in a large display device, a traffic light and the like. Also, a white LED obtained by combining an LED using a nitride semiconductor and a fluorescent material is partially commercialized and is expected to be substituted for currently used lighting equipment when the luminous efficiency is improved in the future.

Furthermore, a violet semiconductor laser device using a nitride semiconductor is now being earnestly studied and developed. As compared with a conventional semiconductor laser device emitting red or infrared light used for an optical disk such as a CD or a DVD, a spot diameter obtained on the optical disk can be reduced in using the violet laser device, and hence, the recording density of the optical disk can be improved.

A violet semiconductor laser device currently practically used employs a ridge structure as shown in FIG. 8. In this structure, a ridge 101 is formed by dry etching, and the lateral mode is controlled by adjusting the width and the depth of the ridge.

In this ridge structure, however, since an electrode 102 should be formed on the ridge 101, the area range of the electrode is restricted. Also, since the ridge 101 is formed by the dry etching, the depth of the ridge is varied, resulting in varying the lateral mode characteristic. Due to such problems in the structure and the fabrication, a violet semiconductor laser device with sufficient performance and reliability has not been realized in a good yield.

On the other hand, a buried type laser device as shown in FIG. 9 is employed for a GaAs-based semiconductor laser device but not yet employed for a GaN-based semiconductor laser device. This is because it is difficult to stably etch a GaN-based semiconductor with small damage. A general method for processing a GaN-based material is dry etching, and when an opening 104 is formed in a current blocking layer 103, if the dry etching is employed, a damage is caused in the vicinity, which degrades the device characteristics. Alternatively, wet etching is generally employed for etching with small damage, but wet etching technique for a GaN-based material with high reproducibility has not been established yet. In addition to such processing technique for a GaN-based semiconductor, crystal of a GaN-based semiconductor is difficult to grow, and it is difficult to regrow a cladding layer 106 with high crystallinity after forming the opening 104 in the current blocking layer 103. This is probably another reason why the buried type structure is not employed.

However, in employing the buried type structure, a distance from an InGaN active layer to the current blocking layer 103 affecting the lateral mode characteristic can be accurately controlled, and serial resistance can be reduced because a contact electrode can be formed in a large area. Thus, the buried type structure is variously advantageous to the ridge structure in the performance and the reliability.

Therefore, some techniques for overcoming the aforementioned problems of the buried type structure peculiar to a GaN-based semiconductor have been proposed.

Japanese Laid-Open Patent Publication No. 2003-78215 discloses a technique to improve the reproducibility of etching for an opening of a current blocking layer by increasing etch selectivity of a GaN-based semiconductor. Specifically, after forming an amorphous current blocking layer on a crystalline cladding layer, the current blocking layer is partly etched by wet etching using a phosphoric acid-containing solution, and thereafter, annealing is performed at a high temperature, so as to crystallize the amorphous current blocking layer.

According to this technique, in etching the amorphous current blocking layer, since an etching ratio between an amorphous layer and a crystalline layer is large, the underlying crystalline cladding layer can be used as an etching stopper, and hence, the etching of the current blocking layer can be well controlled.

However, although the amorphous layer is crystallized through the annealing at a high temperature after forming the opening in the amorphous current blocking layer, crystal of a GaN-based semiconductor is difficult to grow as described above, and a re-crystallized layer obtained through the high temperature annealing does not always have high quality. Furthermore, even when a regrown layer is formed on the current blocking layer with such low crystallinity, the regrown layer is difficult to attain high crystallinity.

Japanese Laid-Open Patent Publication No. 10-93199 discloses a technique to form an opening in a current blocking layer without etching an underlying cladding layer by forming a re-evaporation layer working as an etching stopper between the cladding layer and the current blocking layer. In this case, the re-evaporation layer exposed in the opening of the current blocking layer is made of a material that can be selectively removed through evaporation by annealing after forming the opening in the current blocking layer. This procedure for evaporating the re-evaporation layer can be performed in a MOCVD system, and hence, without exposing the exposed underlying cladding layer to the air but while keeping its surface clean, the formation of a regrown layer can be performed subsequently to the evaporation procedure. Thus, the regrown layer can be formed with high crystallinity.

### SUMMARY OF THE INVENTION

Although the processability of a current blocking layer and the crystallinity of a regrown layer can be improved by employing the technique described in Japanese Laid-Open Patent Publication No. 10-93199, a GaN-based semiconductor layer with high performance and high reliability has not been realized yet, and a GaN-based semiconductor laser device with the buried type structure has not been put to practical use.

The present inventors considered the essential advantageous performance of the buried type structure and made examination on a method for controllably forming an opening in a current blocking layer. As a result, the inventors found a method described below and filed a patent application for the method (Japanese Patent Application No. 2005-253824).

In this method, after forming an active layer sandwiched between cladding layers on a GaN substrate, in forming a current blocking layer on the cladding layer and forming an opening in the current blocking layer, the top face (i.e., a group III face of the current blocking layer is wet etched by a method designated as photoelectrochemical (PEC) etching with the reverse face (i.e., a group V face) of the GaN substrate protected from an etching solution.

The PEC etching is performed with a GaN substrate dipped in an electrolytic solution while externally irradiating an etching target (a current blocking layer in the present case) with UV, and the etching is proceeded through dissolution of the current blocking layer caused by holes generated on the surface of the current blocking layer through the UV irradiation.

The present inventors found that a hole generated through the UV irradiation has a property to move to the face of the group V element of a GaN-based semiconductor and hence the etching is not proceeded on the face of the group III element. The inventors thought that etching of the current blocking layer (the face thereof of the group III element) cannot be stably performed because of this phenomenon. When the current blocking layer was etched with the reverse face (the face of the group V element) of the GaN substrate protected from the etching solution, the etching could be performed stably.

Through application of this etching method, a GaN-based semiconductor laser device with a buried type structure could be stably obtained, and as a result, the characteristics of the semiconductor laser device could be evaluated with high reproducibility.

While evaluating the characteristics of GaN-based semiconductor laser devices with the buried type structure under the circumstances, it was found that some samples had threshold currents of laser oscillation largely different from a design value although they had the same structure as others.

In general, a cross-section of a sample is observed with an electron microscope for confirming the resultant structure of the sample. FIG. 1A shows an electron micrograph of a cross-section of a sample having a threshold current largely different from a design value and FIG. 1B is a schematic diagram thereof.

As shown in FIG. 1B, an n-type AlGaN current blocking layer 2 having an opening 4 is formed on a p-type GaN guiding layer 1, and a p-type GaN guiding layer 3 is formed thereon. (Note: This sample has a structure in which a guiding layer is provided between a cladding layer and an active layer.)

In order to observe such a cross-sectional structure with an electron microscope, reflected electrons are detected so as to obtain contrast derived from a difference in the composition of the crystal, and a difference in the conductivity among respective layers can be obtained as contrast by detecting secondary electrons.

When the present inventors detected secondary electrons in the same region as that shown in FIG. 1A, a secondary electron image as shown in FIG 1C was obtained. FIG. 1D is a schematic diagram thereof.

When FIGS. 1A and 1B are compared with FIGS. 1C and 1D, it is found that a boundary formed by the difference in the composition (shown with an arrow A) is shifted from a boundary formed by the difference in the conductivity (shown with an arrow B). This means that a portion with a given width of the current blocking layer 2 in contact with the side face of the opening 4 is changed to have the n-type conductivity or into a highly resistant layer in the GaN guiding layer 3 that should have the p-type conductivity.

The cause of such a change to the n-type conductivity is not obvious, but the following seems to be one factor: When the p-type GaN guiding layer 3 is regrown, a portion thereof regrown from the side face of the opening 4 easily incorporates an n-type impurity or a defect functioning as a donor is easily caused.

For further examination, samples in which the portions changed to have the n-type conductivity (hereinafter referred to as n-type conductivity changed portions) have different widths are obtained with the growth temperature for the p-type GaN guiding layer 3 changed, and laser oscillation threshold currents of these samples are measured, resulting in obtaining a graph of FIG. 2. The abscissa indicates the growth temperature of the p-type GaN guiding layer 3 and the ordinate indicates the laser oscillation threshold current. As is understood from FIG. 2, the threshold current starts to increase when the growth temperature exceeds 1100° C.

In the samples obtained by employing the various growth temperatures, reflection electron images and secondary electron images are observed with an electron microscope so as to measure the widths of the n-type conductivity changed portions, and the results are plotted on the (upper) abscissa of FIG. 2. Thus, it is found that the increase of the threshold current is concerned with the width of the n-type conductivity changed portion. Specifically, when the width of the n-type conductivity changed portion exceeds 0.15 μm; the threshold current obviously increases.

This phenomenon can be understood as follows: As shown in FIG. 3, a current from a p-type AlGaN cladding layer 5 is confined in the p-type GaN guiding layer 3 where the conductivity is not changed to the n-type and flows to an active layer (not shown) disposed below the guiding layer. As a result, light is emitted from the active layer and a large gain is obtained. On the other hand, the current minimally flows to a portion of the active layer disposed below the n-type AlGaN current blocking layer 2 through an n-type conductivity changed portion 6, and hence, this portion of the active layer works as an absorbing layer. Light confinement in the lateral direction is performed by using a difference in the refractive index between the n-type AlGaN current blocking layer 2 and the p-type GaN guiding layer 3, and hence, light is distributed in a high ratio in a portion where the absorption is caused. This seems to cause the increase of the laser oscillation threshold current.

When the width the n-type conductivity changed portion is increased and a substantial width of the guiding layer is reduced, a resistance component is increased in this portion, which can degrade the electric characteristics.

Such an unexpected change to the n-type conductivity seems to be caused through various factors. Therefore, if the structure or the process for a semiconductor laser device is designed without paying attention to this phenomenon, unexpected variation of the electric characteristics such as a current threshold value may be caused.

The present invention was devised on the basis of the aforementioned finding, and an object of the invention is providing a buried type nitride semiconductor laser device with stable characteristics and a method for fabricating the same.

The nitride semiconductor laser device of this invention includes an active layer sandwiched between cladding layers; and a current blocking layer having an opening for confining a current flowing to the active layer, and a regrown layer is formed on the current blocking layer for covering the opening of the current blocking layer, and the regrown layer is made of a nitride semiconductor layer including In and doped with a p-type impurity.

In the above-described architecture, the regrown layer covering the opening of the current blocking layer is made of the nitride semiconductor layer including In and doped with a p-type impurity, so that a portion in contact with the side face of the opening can be prevented from being changed to have the n-type conductivity. Accordingly, a buried type nitride semiconductor laser device having stable characteristics can be provided.

In this case, the nitride semiconductor layer including In is preferably made of InGaN or AlInGaN. Since InGaN can incorporate a p-type impurity of a high concentration, the change to the n-type conductivity can be suppressed in the formation of the regrown layer. Also, since AlInGaN has a larger band gap than InGaN, the change to the n-type conductivity can be suppressed as well as degradation of the laser characteristics can be prevented by suppressing absorption of laser beams.

Furthermore, the regrown layer is preferably made of a multilayered film including the nitride semiconductor layer including In and a thin film of GaN or AlGaN formed below the nitride semiconductor layer including In. When the thin film of GaN with high crystallinity is formed at the early stage of the formation of the nitride semiconductor layer including In, the change to the n-type conductivity can be suppressed, and hence, the regrown layer can be formed with high crystallinity. Alternatively, when the thin film of AlGaN minimally growing in the lateral direction is formed at the early stage of the formation of the nitride semiconductor layer including In, the change to the n-type conductivity can be further suppressed.

Moreover, the current blocking layer is preferably made of GaN or AlGaN doped with an n-type impurity. When a PN junction is formed between an n-type current blocking layer and a p-type regrown layer, the current blocking effect can be more remarkably exhibited.

It is noted that the current blocking layer preferably has a lower refractive index than the regrown layer. Also, the regrown layer may correspond to a part of the cladding layers.

The other nitride semiconductor laser device of this invention includes an active layer sandwiched between cladding layers; and a current blocking layer having an opening for confining a current flowing to the active layer, and a regrown layer made of a nitride semiconductor doped with a p-type impurity is formed on the current blocking layer for covering the opening of the current blocking layer, a portion of the regrown layer buried in the opening of the current blocking layer and adjacent to a side face of the opening is changed to have an n-type conductivity, and the portion changed to have an n-type conductivity has a width of 0.15 μm or less.

In the above-described architecture, an n-type conductivity changed portion formed in the regrown layer buried in the opening of the current blocking layer and adjacent to the side face of the opening is made to have a width of 0.15 μm or less. Accordingly, a buried type nitride semiconductor laser device with stable characteristics can be provided.

The method of this invention for fabricating a nitride semiconductor laser device including an active layer sandwiched between cladding layers and a current blocking layer having an opening for confining a current flowing to the active layer, includes the steps of forming the active layer sandwiched between the cladding layers on a substrate; forming the current blocking layer on one of the cladding layers; forming the opening for confining the current flowing to the active layer by etching a part of the current blocking layer; and forming a regrown layer on the current blocking layer for covering the opening of the current blocking layer, and the regrown layer is made of a nitride semiconductor layer including In and doped with a p-type impurity.

In the above-described fabrication method, the regrown layer covering the opening of the current blocking layer is made of the nitride semiconductor layer including In and doped with a p-type impurity, so that a portion in contact with the side face of the opening can be prevented from being changed to have the n-type conductivity. Accordingly, a buried type nitride semiconductor laser device having stable characteristics can be provided.

In this case, the step of forming a regrown layer preferably includes a sub-step of forming a thin film of GaN or AlGaN on the current blocking layer for covering the opening of the current blocking layer; and a sub-step of forming the nitride semiconductor layer including In and doped with a p-type impurity on the thin film.

Furthermore, the nitride semiconductor layer including In is preferably made of InGaN or AlInGaN.

The other method of this invention for fabricating a nitride semiconductor laser device including an active layer sandwiched between cladding layers and a current blocking layer having an opening for confining a current flowing to the active layer, includes the steps of forming the active layer sandwiched between the cladding layers on a substrate; forming the current blocking layer on one of the cladding layers; forming the opening for confining the current flowing to the active layer by etching a part of the current blocking layer; and forming a regrown layer made of a nitride semiconductor layer doped with a p-type impurity on the current blocking layer for covering the opening of the current blocking layer, the step of forming a regrown layer includes a first sub-step of depositing the nitride semiconductor layer at a first growth temperature where lateral growth of the nitride semiconductor layer is slow; and a second sub-step of depositing the nitride semiconductor layer at a second growth temperature where the nitride semiconductor layer is grown with high crystallinity.

In the above-described fabrication method, the nitride semiconductor layer is formed in two steps, namely, the deposition is performed at the first growth temperature where the lateral growth is slow at the early stage of the growth of the regrown layer, and subsequently, the deposition is performed at the second growth temperature where high crystallinity is attained. Accordingly, the change to the n-type conductivity of a portion in contact with the side face of the opening can be suppressed.

It is noted that the first growth temperature is preferably lower than the second growth temperature.

According to the nitride semiconductor laser device and the method for fabricating the same of this invention, a regrown layer covering an opening of a current blocking layer is made of a nitride semiconductor layer including In and doped with a p-type impurity, so that a portion in contact with the side face of the opening can be prevented from being changed to have the n-type conductivity. Accordingly, a buried type nitride semiconductor laser device having stable characteristics can be provided.

Furthermore, when the regrown layer is made of a multilayered film including a thin film of GaN with high crystallinity formed below the nitride semiconductor layer including In, the change to the n-type conductivity is suppressed, so as to form the regrown layer with high crystallinity.

Alternatively, when the regrown layer is made of a multilayered film including a thin film of AlGaN minimally growing in the lateral direction formed below the nitride semiconductor layer including In, the change to the n-type conductivity can be further suppressed.

### BRIEF DESCRIPTION OF THE DRAWINGS

FIGS. 1A, 1B, 1C and 1D are electron micrographs and schematic diagrams thereof for explaining a problem to be solved by a nitride semiconductor laser device of this invention;

FIG. 2 is a graph of a laser oscillation threshold current concerned with the problem to be solved by the invention;

FIG. 3 is a schematic diagram for showing a phenomenon of a change to the n-type conductivity concerned with the problem to be solved by the invention;

FIG. 4 is a cross-sectional view for schematically showing the architecture of a nitride semiconductor laser device according to Embodiment 1 of the invention;

FIG. 5 is a cross-sectional view for showing a specific architecture of the nitride semiconductor laser device of Embodiment 1;

FIG. 6 is a graph of a laser oscillation threshold current in the invention;

FIGS. 7A, 7B, 7C and 7D are cross-sectional views for schematically showing procedures in a method for fabricating a nitride semiconductor laser device according to Embodiment 2 of the invention;

FIG. 8 is a cross-sectional view for showing the architecture of a conventional nitride semiconductor laser device having a ridge structure; and

FIG. 9 is a cross-sectional view for showing the architecture of a conventional nitride semiconductor laser device having a buried type structure.

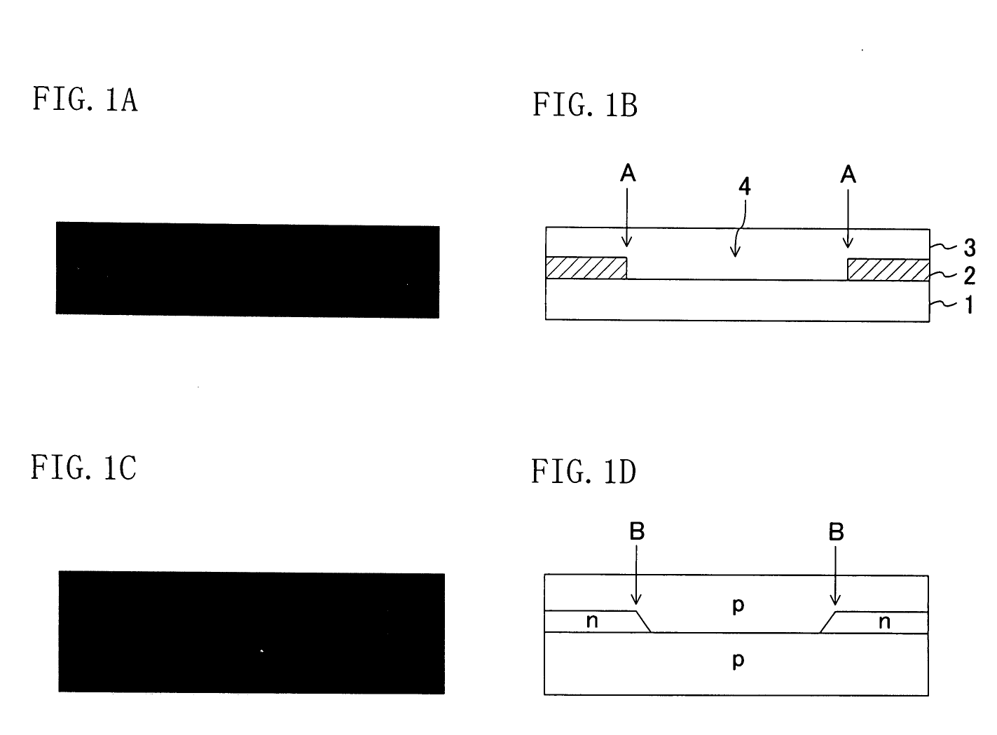

### DETAILED DESCRIPTION OF THE INVENTION

Now, preferred embodiments of the invention will be described with reference to the accompanying drawings. In the drawings referred to below, like reference numerals are used to refer to like elements for simplifying the description. It is noted that the present invention is not limited to the embodiments described below.

### Embodiment 1

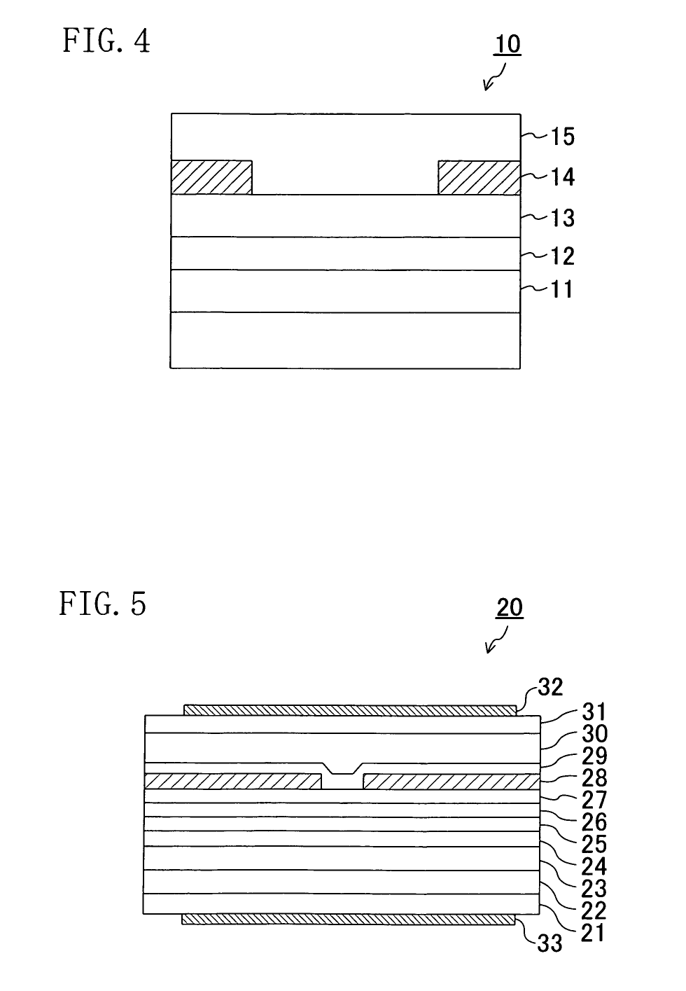

FIG. 4 is a cross-sectional view for schematically showing the basic architecture of a nitride semiconductor laser device according to Embodiment 1 of the invention.

The nitride semiconductor laser device 10 has a buried type structure including an active layer 12 sandwiched between an n-type cladding layer 11 and a p-type cladding layer 13 and a current blocking layer 14 having an opening for confining a current flowing to the active layer 12. In this buried type structure, a regrown layer 15 of a nitride semiconductor layer including In and doped with a p-type impurity is formed on the current blocking layer 14 so as to cover the opening of the current blocking layer 14.

Although the regrown layer 15 generally corresponds to a part of the p-type cladding layer, its function is not herein limited to this but various other functions (such as the function as a guiding layer) may be provided in accordance with the characteristics of the semiconductor laser device 10.

In this invention, the regrown layer 15 is made of a nitride semiconductor including In because the nitride semiconductor including In can incorporate a p-type impurity of a high concentration as compared with a GaN or AlGaN material conventionally used for a cladding layer or a guiding layer. Specifically, when the nitride semiconductor layer including In is doped with an impurity of a high concentration to the extent that inversion to the n-type conductivity is not caused, change to the n-type conductivity of the regrown layer 15 can be effectively suppressed in the formation of the regrown layer 15.

As the nitride semiconductor including In, InGaN, AlInGaN or the like may be used. Since InGaN has a smaller band gap than GaN, AlInGaN with a larger band gap may be used in the case where it is apprehended that InGaN absorbs laser beams so as to degrade the laser characteristics.

The phenomenon of the change to the n-type conductivity seems to be caused at the early stage of the formation of the regrown layer 15, namely, at a stage where lateral growth starts from the side face of the opening of the current blocking layer 14. Therefore, at the early stage of the formation of the regrown layer 15, a thin film of AlGaN minimally growing in the lateral direction may be first formed so as to form the nitride semiconductor layer including In for suppressing the change to the n-type conductivity thereon. When the regrown layer 15 is made of such a multilayered film, the change to the n-type conductivity can be further definitely suppressed.

Furthermore, the regrown layer 15 should have high crystallinity for exhibiting its essential function (as a cladding layer or a guiding layer). Therefore, at the early stage of the formation of the nitride semiconductor layer including In, a thin film of GaN with high crystallinity may be first formed so as to form the nitride semiconductor layer including In for suppressing the change to the n-type conductivity thereon. When the regrown layer 15 is made of such a multilayered film, the change to the n-type conductivity can be suppressed as well as the regrown layer 15 attains high crystallinity.

In this invention, the material for the current blocking layer 14 is not particularly specified, and for exhibiting the current blocking effect, the current blocking layer 14 is preferably made of a GaN layer or an AlGaN layer doped with an n-type impurity. This is because the current blocking effect can be improved by forming a PN junction between an n-type current blocking layer and a p-type regrown layer.

Moreover, for improving the light confining effect, the refractive index of the current blocking layer 14 is preferably lower than that of the regrown layer 15.

Next, an exemplified specific architecture of a nitride semiconductor layer device 20 according to the present invention will be described with reference to FIG. 5.

An n-GaN layer 22, an n-Al_{0.06}Ga_{0.94}N cladding layer 23, an n-GaN guiding layer 24, an InGaN MQW active layer 25, a p-Al_{0.15}Ga_{0.85}N overflow suppressing layer 26, a p-GaN guiding layer 27 and an n-Al_{0.15}Ga_{0.85}N current blocking layer 28 are successively formed on a 2-inch GaN substrate 21.

An opening is formed in the n-Al_{0.15}Ga_{0.85}N current blocking layer 28, and a p-InGaN guiding layer 29, a p-AlGaN cladding layer 30 and a p-GaN contact layer 31 are regrown on a portion of the p-GaN guiding layer 27 exposed in the opening and on the n-Al_{0.15}Ga_{0.85}N current blocking layer 28. A p-type electrode 32 is formed on the p-GaN contact layer 31, and an n-type electrode 33 is formed on a face of the GaN substrate 21 where the grown layers are not formed.

In this case, a current flows through the p-InGaN guiding layer 29, and light of a wavelength of 405 nm is emitted from the MQW active layer 25. Also, the light confinement in a direction parallel to the active layer 25 is performed by using a difference in the refractive index between the n-Al_{0.15}Ga_{0.85}N current blocking layer 28 and the p-InGaN guiding layer 29.

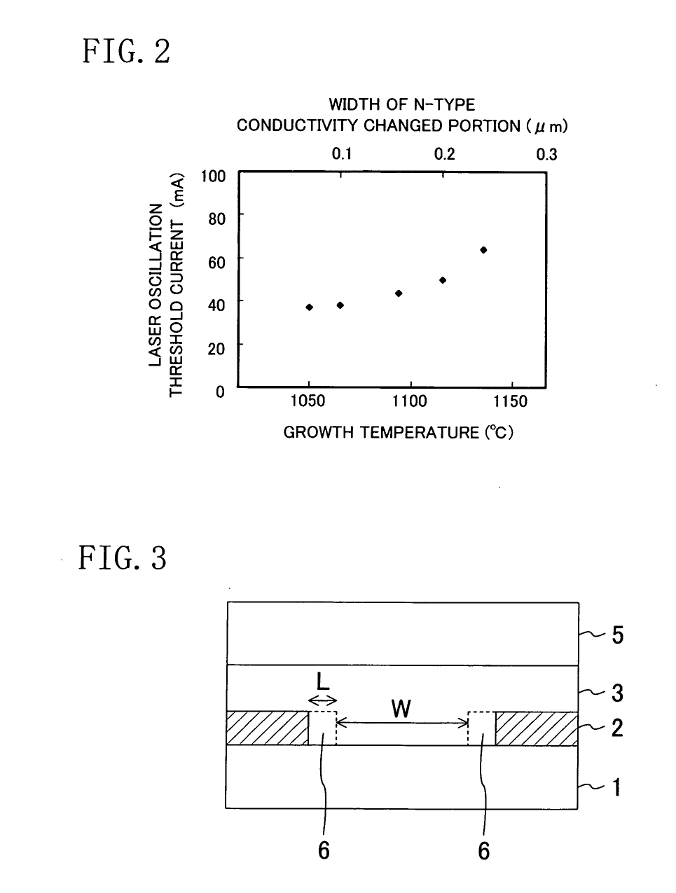

The nitride semiconductor layer including In is used as the regrown layer in this embodiment. However, also in the case where a nitride semiconductor layer not including In (such as a GaN layer or an AlGaN layer) is used, a buried type nitride semiconductor laser device with stable characteristics can be obtained when an n-type conductivity changed portion formed adjacent to the side face of the opening in the regrown layer buried in the opening of the current blocking layer has a width of 0.15 μm or less as shown in FIG. 2. In the case where, for example, a GaN layer is formed as the regrown layer, the width of the n-type conductivity changed portion can be suppressed to 0.15 μm or less by forming the GaN layer at a lower temperature (of 1050° C. through 1080° C.) than the general growth temperature (of 1100° C. through 1130° C.) as shown in FIG. 2.

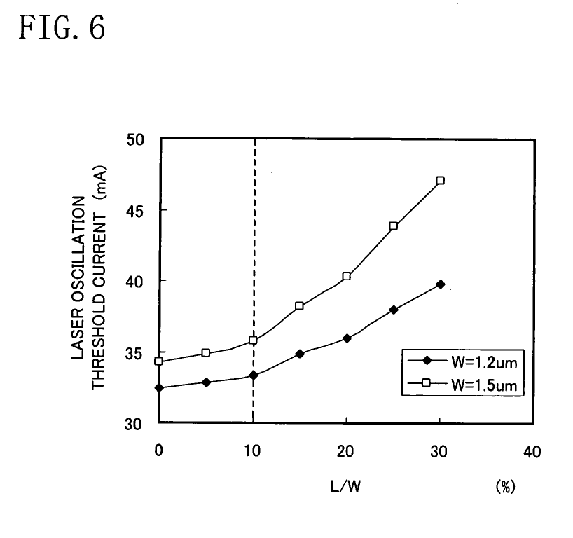

In addition, FIG. 6 is a graph showing the result of the laser oscillation threshold current calculated through simulation in the case where the ratio (L/W) is changed in the architecture shown in FIG. 3, wherein L is the width of the n-type conductivity changed portion 6 and W is the width of the region where the n-type conductivity is not changed in the regrown layer 3 buried in the opening of the current blocking layer 2. FIG. 6 shows that when L/W exceeds 10%, the laser oscillation threshold current increases in both cases of 1.2 μm W and 1.5 μm W. Accordingly, 10% or lower L/W is preferable for obtaining a nitride semiconductor laser device having stable characteristics.

### Embodiment 2

FIGS. 6A through 6D are cross-sectional views for schematically showing procedures in a method for fabricating a nitride semiconductor laser device according to Embodiment 2 of the invention.

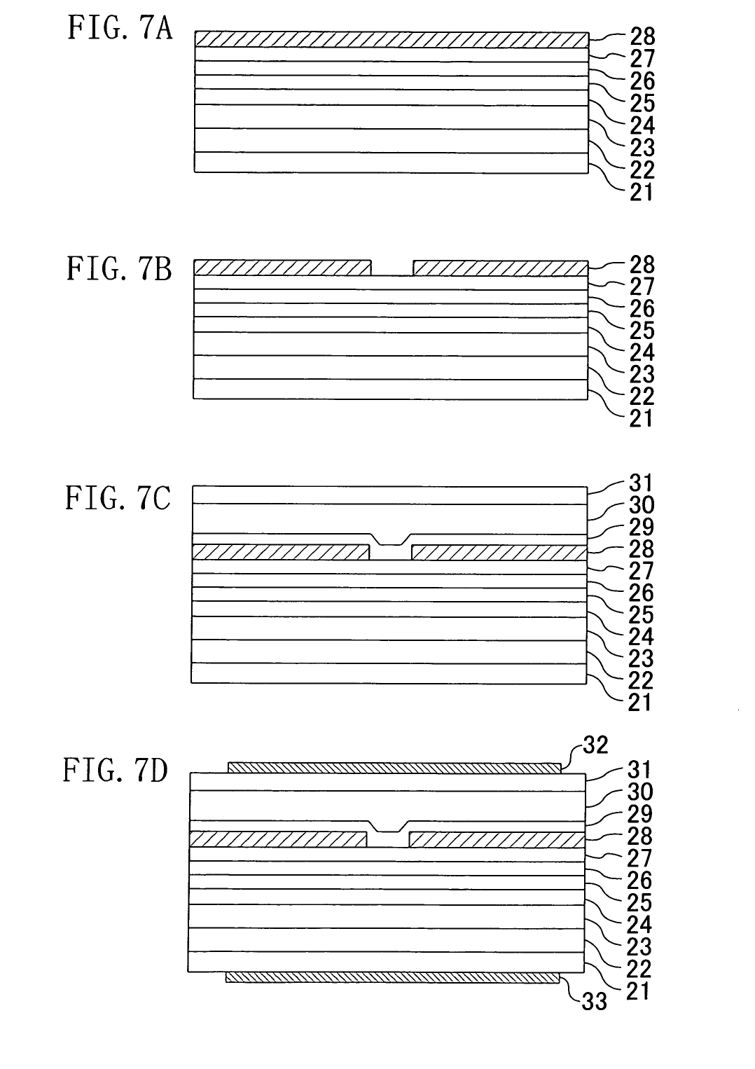

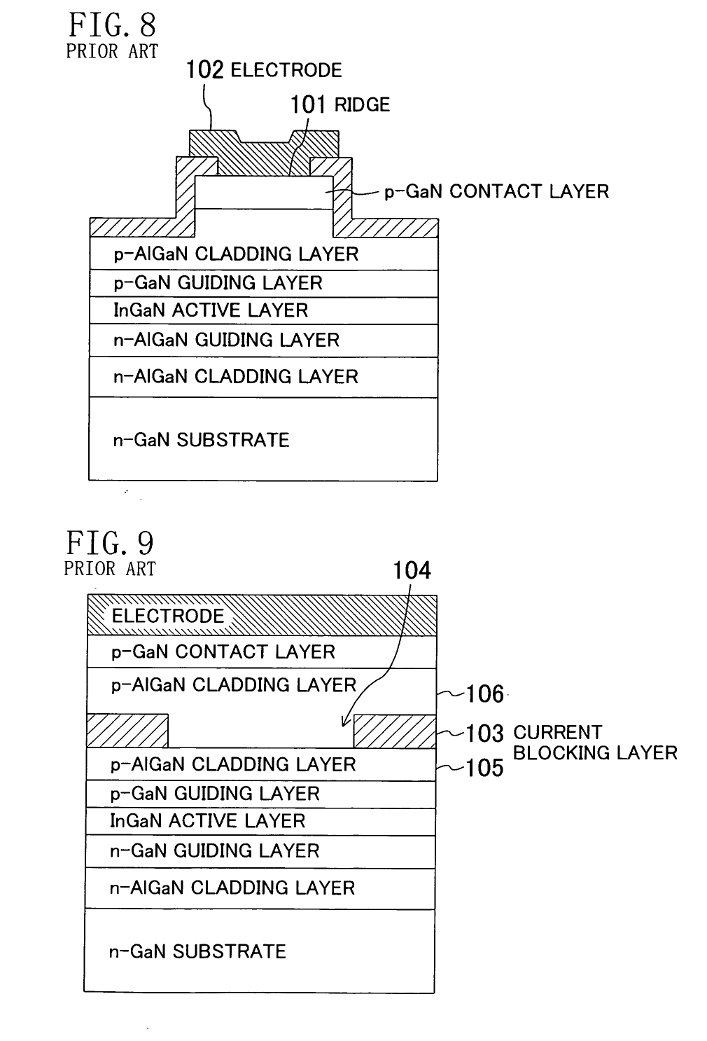

First, as shown in FIG. 7A, an n-GaN layer 22, an n-Al_{0.06}Ga_{0.94}N cladding layer 23, an n-GaN guiding layer 24, an InGaN MQW active layer 25, a p-Al_{0.15}Ga_{0.85}N overflow suppressing layer 26, a p-GaN guiding layer 27 and an n-Al_{0.15}Ga_{0.85}N current blocking layer 28 are successively formed on a 2-inch GaN substrate 21.

Next, as shown in FIG. 7B, a part of the n-Al_{0.15}Ga_{0.85}N current blocking layer 28 is removed through etching. At this point, when the aforementioned PEC etching is employed, the etching can be stably performed without removing the underlying p-GaN guiding layer 27. It is noted that a protection film (not shown) of an oxide film or the like is formed on the rear face of the GaN substrate 21 at this point.

Then, as shown in FIG. 7C, a p-InGaN guiding layer 29, a p-AlGaN cladding layer 30 and a p-GaN contact layer 31 are regrown on the n-Al_{0.15}Ga_{0.85}N current blocking layer 28.

Ultimately, as shown in FIG. 7D, the resistance of the p-type layers is lowered by performing activation annealing in a nitrogen atmosphere at 780° C. for 20 minutes. Thereafter, a p-type electrode 32 is formed on the p-type contact layer 31. The p-type electrode 32 is preferably made of a multilayered film including Ni or Pd. Subsequently, the thickness of the GaN substrate 21 is reduced by polishing a group V face of the GaN substrate 21, and an n-type electrode 33 is formed on the polished face. The n-type electrode 33 is preferably made of a multilayered film including Ti or V.

Although the present invention has been described in preferred embodiments, the embodiments are not restrictive but can be variously modified. For example, although the nitride semiconductor layer including In is used as the regrown layer in Embodiment 2, even when a nitride semiconductor layer not including In such as a GaN layer or an AlGaN layer is used, the change to the n-type conductivity can be effectively suppressed by growing the regrown layer in two steps of growth temperatures. Specifically, as shown in FIG. 2, at the early stage of the formation of the regrown layer, a first stage of the growth is performed at a temperature lower than a general growth temperature (i.e., a temperature where the lateral growth is slow), and thereafter, a second stage of the growth is performed at the general growth temperature (i.e., a temperature for attaining high crystallinity). Thus, a regrown layer with high crystallinity can be formed while suppressing the change to the n-type conductivity.

What is claimed is:

1. A nitride semiconductor laser device comprising:
an active layer sandwiched between cladding layers; and
a current blocking layer having an opening for confining a current flowing to said active layer,
wherein a regrown layer is formed on said current blocking layer for covering said opening of said current blocking layer, and
said regrown layer is made of a nitride semiconductor layer including In and doped with a p-type impurity.

2. The nitride semiconductor laser device of claim 1,
wherein said nitride semiconductor layer including In is made of InGaN or AlInGaN.

3. The nitride semiconductor laser device of claim 1,
wherein said regrown layer is made of a multilayered film including said nitride semiconductor layer including In and a thin film of GaN or AlGaN formed below said nitride semiconductor layer including In.

4. The nitride semiconductor laser device of claim 1,
wherein said current blocking layer is made of GaN or AlGaN doped with an n-type impurity.

5. The nitride semiconductor laser device of claim 1,
wherein said current blocking layer has a lower refractive index than said regrown layer.

6. The nitride semiconductor laser device of claim 1,
wherein said regrown layer corresponds to a part of said cladding layers.

7. The nitride semiconductor laser device of claim 1,
wherein a region adjacent to the side face of said opening in said regrown layer buried in said opening of said current blocking layer is changed to an n-type conductivity, and
the width of said n-type conductivity changed region is 10% or lower of the width of a region where said n-type conductivity is not changed in said regrown layer buried in the opening.

8. A nitride semiconductor laser device comprising:
an active layer sandwiched between cladding layers; and
a current blocking layer having an opening for confining a current flowing to said active layer,
wherein a regrown layer made of a nitride semiconductor doped with a p-type impurity is formed on said current blocking layer for covering said opening of said current blocking layer,
a portion of said regrown layer buried in said opening of said current blocking layer and adjacent to a side face of said opening is changed to have an n-type conductivity, and
said portion changed to have an n-type conductivity has a width of 0.15 μm or less.

9. A method for fabricating a nitride semiconductor laser device including an active layer sandwiched between cladding layers and a current blocking layer having an opening for confining a current flowing to said active layer, comprising the steps of:
forming said active layer sandwiched between said cladding layers on a substrate;
forming said current blocking layer on one of said cladding layers;
forming said opening for confining the current flowing to said active layer by etching a part of said current blocking layer; and
forming a regrown layer on said current blocking layer for covering said opening of said current blocking layer,
wherein said regrown layer is made of a nitride semiconductor layer including In and doped with a p-type impurity.

10. The method for fabricating a nitride semiconductor laser device of claim 9,
wherein the step of forming a regrown layer includes:
a first sub-step of forming a thin film of GaN or AlGaN on said current blocking layer for covering said opening of said current blocking layer; and
a second sub-step of forming said nitride semiconductor layer including In and doped with a p-type impurity on said thin film.

11. The method for fabricating a nitride semiconductor laser device of claim 9,
wherein said nitride semiconductor layer including In is made of InGaN or AlInGaN.

12. A method for fabricating a nitride semiconductor laser device including an active layer sandwiched between cladding layers and a current blocking layer having an opening for confining a current flowing to said active layer, comprising the steps of:
forming said active layer sandwiched between said cladding layers on a substrate;
forming said current blocking layer on one of said cladding layers;
forming said opening for confining the current flowing to said active layer by etching a part of said current blocking layer; and
forming a regrown layer made of a nitride semiconductor layer doped with a p-type impurity on said current blocking layer for covering said opening of said current blocking layer,
wherein the step of forming a regrown layer includes:
a first sub-step of depositing said nitride semiconductor layer at a first growth temperature where lateral growth of said nitride semiconductor layer is slow; and
a second sub-step of depositing said nitride semiconductor layer at a second growth temperature where said nitride semiconductor layer is grown with high crystallinity.

13. The method for fabricating a nitride semiconductor laser device of claim 12,
wherein said first growth temperature is lower than said second growth temperature.

14. The method for fabricating a nitride semiconductor laser device of claim 9 or 12,
wherein a region adjacent to the side face of said opening in said regrown layer buried in said opening of said current blocking layer is changed to an n-type conductivity, and
the width of said n-type conductivity changed region is 10% or lower of the width of a region where said n-type conductivity is not changed in said regrown layer buried in the opening.
